(19) United States
(12) Patent Application Publication
(10) Pub. No.: US 2009/0317565 A1
(43) Pub. Date: Dec. 24, 2009

(54) PLASMA CVD EQUIPMENT

(75) Inventor: Satoshi MAEBASHI, Nirasaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/546,457

(22) Filed: Aug. 24, 2009

Related U.S. Application Data
(63) Continuation of application No. 11/597,366, filed on Nov. 22, 2006.

(30) Foreign Application Priority Data
Jun. 3, 2004 (JP) 2004-165630

(51) Int. Cl. C23C 16/50; C23C 16/00

(52) U.S. Cl. 427/569; 118/723 R

(57) ABSTRACT

Plasma CVD equipment by which increase of a voltage applied on a board to be processed is suppressed, a board is prevented from being damaged and a yield is improved. In the plasma CVD equipment, a material gas is decomposed by plasma discharge in a chamber which can be depressurized, and a conductive film is formed on a board to be processed. When a cumulative number of times of film forming processes reaches a prescribed value, the inside of the chamber is dry-cleaned to be returned to the initial state. The plasma CVD equipment is provided with an insulator stage whereupon a board to be processed is placed in the chamber; a grounding electrode buried in the stage; a high-frequency electrode provided in the chamber by facing the grounding electrode; a high-frequency power supply for supplying the high-frequency electrode with high-frequency waves for generating plasma; and a fixed capacitor inserted between the grounding electrode and the grounding potential for suppressing the increase of the voltage applied on the board due to deterioration of stage impedance between the grounding electrode and the board as the cumulative number of times of the film forming processes increases from the initial state.

### CROSS-REFERENCE TO RELATED APPLICATIONS:

The present application is a continuation application of and claims priority to U.S. application Ser. No. 11/597,366, filed on Nov. 22, 2006, of which the entire content is hereby incorporated by reference, with the present application also claiming priority to predecessors of the '366 application as follows: U.S. application Ser. No. 11/597,366 is a national stage application of PCT/JP05/009373, filed on May 23, 2005, which is based upon and claims the benefit of priority from prior Japanese Application JP 2004-165630, filed on Jun. 3, 2004.

### FIELD OF THE INVENTION

The present invention relates to a plasma CVD equipment in which a film formation process employing a chemical vapor deposition (CVD) is performed on a substrate to be processed by using a plasma.

### BACKGROUND OF THE INVENTION

A plasma CVD is a film forming method whereby a reactive process gas is decomposed into chemically active ions and/or radicals using the energy of a plasma in a depressurized chamber, thereby forming a film on a substrate to be processed through a surface reaction thereof.

It is typical in a plasma CVD equipment for formation of a metallic film, e.g., a Ti film, that a substrate is supported on a stage within a chamber and a surface reaction is promoted by applying heat to the substrate from the stage. For this reason, a deposition is formed around the substrate (particularly, on the top or side surface of the stage) concomitantly with the formation of a film on the substrate.

Further, such deposition formed around the substrate interferes with the state of a plasma or becomes particles when peeled off. Taking this into account, the chamber is dry-cleaned at every 500^{th} cycle of the film formation process (for every 500 substrates processed) to restore respective parts in the chamber to an initial state free from the deposition.

However, even with the method of periodically dry-cleaning the chamber as noted above, it is often the case that, depending on process conditions or device conditions, the substrate is subject to damage at a later stage of a dry-cleaning cycle (e.g., after processing 200 substrates), which in turn leads to reduction in the production yield.

Investigation conducted by the present inventor has revealed that, as the film formation process is performed repeatedly, the deposition in the chamber is accumulated or increased, which causes change in impedance. This results in a gradual increase in the voltage applied to the substrate (in the potential difference of the substrate). Consequently, it has been concluded that, if the film formation process is repeatedly executed, the substrate could get damaged by an abnormal electric discharge or the like.

One of solutions to this problem is to shorten the dry-cleaning cycle. However, a lengthy period of time (usually, exceeding five hours) has to be devoted in conducting a dry-cleaning operation. It is, therefore, undesirable to shorten the dry-cleaning cycle (that is, to increase the frequency of the dry-cleaning operation) in terms of productivity.

### SUMMARY OF THE INVENTION

In view of the foregoing and other problems, it is an object of the present invention to provide a plasma CVD equipment that can suppress any increase in the voltage applied to a substrate to be processed despite the repeated execution of film formation process during a dry-cleaning cycle, thereby avoiding any possible damage to the substrate and improving a production yield.

In order to achieve the above object, in accordance with a first plasma CVD apparatus, there is provided a plasma CVD apparatus for decomposing a source gas by a plasma discharge within a chamber capable of being depressurized to form a conductive film on a substrate to be processed, and dry-cleaning an inside of the chamber to restore the chamber to an initial state if a cumulative number of times of a film formation process reaches a predetermined value, the apparatus including an insulator stage for supporting the substrate to be processed within the chamber; a grounding electrode embedded in the stage; a high-frequency electrode provided within the chamber to face the grounding electrode; a high-frequency power supply for supplying a high frequency for generation of a plasma to the high-frequency electrode; and a fixed capacitor inserted between the grounding electrode and a ground for suppressing an increase in a voltage applied to the substrate, wherein the increase in the voltage is caused by reduction in a stage impedance between the grounding electrode and the substrate as the cumulative number of times of film formation process is increased from the initial state.

In the first plasma CVD equipment noted above, even if the stage impedance is reduced in the midst of the dry cleaning cycle, the impedance insertion effect or voltage dividing effect provided by the fixed capacitor compensates the reduction in the stage impedance, making it possible to suppress any increase in the voltage applied to the substrate.

In accordance with one preferred configuration thereof, a capacitance of the capacitor is selected such that a total impedance of an impedance of the capacitor and the stage impedance at a time when one period of the film formation process is completed is substantially identical or approximate to the stage impedance at a time when said one period is started, wherein the film formation process is repeated in a predetermined number of times within said one period.

In accordance with a second plasma CVD apparatus, there is provided a plasma CVD apparatus for decomposing a source gas by a plasma discharge within a chamber capable of being depressurized to form a conductive film on a substrate to be processed, and dry-cleaning an inside of the chamber to restore the chamber to an initial state if a cumulative number of times of film formation process reaches a predetermined value, the apparatus including an insulator stage for supporting the substrate to be processed within the chamber; a grounding electrode embedded in the stage; a high-frequency electrode provided within the chamber to face the grounding electrode; a high-frequency power supply for supplying a high frequency for generation of a plasma to the high-frequency electrode; and a fixed capacitor inserted between the grounding electrode and a ground for suppressing an increase in a voltage applied to the substrate, wherein the increase in the voltage is caused by reduction in a chamber impedance between the high-frequency electrode and the grounding electrode as the cumulative number of times of film formation process is increased from the initial state.

In the second plasma CVD equipment noted above, even if the stage impedance is reduced in the midst of the dry cleaning cycle, the impedance insertion effect or voltage dividing effect provided by the fixed capacitor could compensate the reduction in the stage impedance, making it possible to suppress any increase in the voltage applied to the substrate. In accordance with one preferred configuration thereof, a capacitance of the capacitor is selected such that a total impedance of an impedance of the capacitor and the chamber impedance at a time when one period of the film formation process is completed is substantially identical or approximate to the chamber impedance at a time when said one period is started, wherein the film formation process is repeated in a predetermined number of times within said one period.

In accordance with a third plasma CVD apparatus, there is provided a plasma CVD apparatus for decomposing a source gas by a plasma discharge within a chamber capable of being depressurized to form a conductive film on a substrate to be processed, and dry-cleaning an inside of the chamber to restore the chamber to an initial state if a cumulative number of times of film formation process reaches a predetermined value, the apparatus including an insulator stage for supporting the substrate to be processed within the chamber; a grounding electrode embedded in the stage; a high-frequency electrode provided within the chamber to face the grounding electrode; a high-frequency power supply for supplying a high frequency for generation of a plasma to the high-frequency electrode; a variable capacitor inserted between the grounding electrode and a ground; and a control unit for variably controlling the variable capacitor for suppressing an increase in a voltage applied to the substrate, wherein the increase in the voltage is caused by reduction in a stage impedance between the grounding electrode and the substrate as the cumulative number of times of film formation process is increased from the initial state.

In the third plasma CVD equipment noted above, even if the stage impedance is reduced in the midst of the dry cleaning cycle, the impedance insertion effect or voltage dividing effect provided by the variable capacitor could compensate the reduction in the stage impedance, making it possible to suppress any increase in the voltage applied to the substrate. In accordance with one preferred configuration thereof, the control unit controls a capacitance of the capacitor variably in such a manner that a total impedance of an impedance of the capacitor and the stage impedance is maintained to be substantially constant throughout one period of the film formation process, wherein the film formation process is repeated in a predetermined number of times within said one period.

In accordance with a fourth plasma CVD apparatus, there is provided a plasma CVD apparatus for decomposing a source gas by a plasma discharge within a chamber capable of being depressurized to form a conductive film on a substrate to be processed, and dry-cleaning an inside of the chamber to restore the chamber to an initial state if a cumulative number of times of film formation process reaches a predetermined value, the apparatus including an insulator stage for supporting the substrate to be processed within the chamber; a grounding electrode embedded in the stage; a high-frequency electrode provided within the chamber to face the grounding electrode; a high-frequency power supply for supplying a high frequency for generation of a plasma to the high-frequency electrode; a variable capacitor inserted between the grounding electrode and a ground; and a control unit for variably controlling the variable capacitor for suppressing an increase in a voltage applied to the substrate, wherein the increase in the voltage is caused by reduction in a chamber impedance between the high-frequency electrode and the grounding electrode and the substrate as the cumulative number of times of film formation process is increased from the initial state.

In the fourth plasma CVD equipment noted above, even if the stage impedance is reduced in the midst of the dry cleaning cycle, the impedance insertion effect or voltage dividing effect provided by the variable capacitor could compensate the reduction in the stage impedance, making it possible to suppress any increase in the voltage applied to the substrate. In accordance with one preferred configuration thereof, the control unit controls a capacitance of the capacitor variably in such a manner that a total impedance of an impedance of the capacitor and the chamber impedance is maintained to be substantially constant throughout one period of the film formation process, wherein the film formation process is repeated in a predetermined number of times within said one period.

In the plasma CVD equipment of the present invention, the substrate is mounted on the insulator stage to thereby create a capacitance (stage capacitance) between the grounding electrode and the substrate. As a material for the stage, it is preferable to use AkN that exhibits a high thermal conductivity. In the stage, it is preferred that a heating element is provided below the grounding electrode and the heat generated by the heating element is transferred to an insulator on the stage through the grounding electrode in a mesh-like shape. The high frequency for generating the plasma may be an arbitrary one but should preferably be in the range of 450 kHz to 2 MHz, where the deposition (electrically conductive film) formed on the substrate and the electrode as well as around the substrate is substantially negligible. According to the present invention, a great advantage is attained in the plasma CVD equipment for formation of a metal film such as a Ti film or the like.

By virtue of the configuration and operation described above, the plasma CVD equipment of the present invention can suppress any increase in the voltage applied to a substrate to be processed despite the repeated execution of film formation process during a dry-cleaning cycle, thereby avoiding any possible damage to the substrate and improving a production yield.

### BRIEF DESCRIPTION OF THE DRAWINGS

FIG. 1 shows a view illustrating the major configuration of a plasma CVD equipment in accordance with one embodiment of the present invention.

FIG. 2 illustrates a view showing an equivalent circuit of the high frequency impedance within a chamber of the plasma CVD equipment shown in FIG. 1.

FIG. 3 depicts a view schematically representing a potential distribution and an operation of the present invention in the equivalent circuit illustrated in FIG. 2.

FIG. 4 describes a view schematically representing, by way of reference, a potential distribution in an equivalent circuit modified from the present invention.

FIG. 5 offers a view explaining one exemplary method for selecting the capacitance of a capacitor in the plasma CVD equipment shown in FIG. 1.

FIG. 6 sets forth a view showing the major configuration of a plasma CVD equipment in accordance with an embodiment of the present invention.

FIG. 7 provides a view explaining one exemplary method for variably controlling the capacitance of a capacitor in the plasma CVD equipment shown in FIG. 6.

FIG. 8 presents a view schematically representing an operation of the present invention in the plasma CVD equipment shown in FIG. 6.

### EXPLANATION OF REFERENCE NUMERALS

10: chamber

12: stage

18: grounding electrode

20: heater

22: capacitor

24: heater power supply

26: upper electrode (shower head)

28: gas supply unit

34: high-frequency power supply

36: matching unit

44: gas evacuation unit

50: control unit

### DETAILED DESCRIPTION OF THE PREFERRED EMBODIMENTS

Preferred embodiments of the present invention will now be described with reference to the accompanying drawings.

### First Embodiment

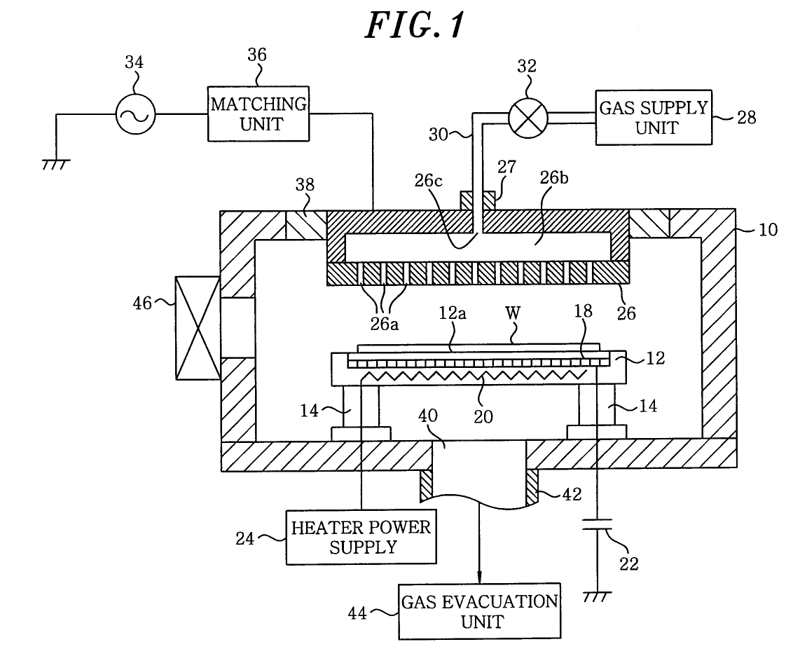

FIG. 1 shows the major configuration of a plasma CVD equipment in accordance with one embodiment of the present invention. The plasma CVD equipment is configured as a capacitively-coupled parallel plate plasma CVD equipment for forming a Ti film and includes a cylindrical chamber 10 made of metal, e.g., aluminum, stainless steel or the like.

Provided within the chamber 10 is a disk-like stage 12 for supporting a substrate to be processed, e.g., a semiconductor wafer W. In the exemplary configuration illustrated, leg-like supports 14 extend upright from the bottom of the chamber 10 to horizontally support the stage 12 at a position of a predetermined height. A guide ring 16 for guiding the semiconductor water W to a water mounting surface 12a at the time of loading the wafer is provided along the top peripheral edge of the stage 12. Although not shown in the drawings, there is also provided a lift mechanism (including a lift pin, an up-down drive unit and the like) for raising and lowering a semiconductor wafer W with respect to the stage 12 during the course of wafer loading and unloading operations.

While the stage 12 is mainly made of an insulating material, at least the wafer mounting surface 12a thereof is made of an insulating material with high heat conductivity, e.g., AlN. A mesh-like grounding electrode 18 is arranged below the wafer mounting surface 12a, and a heater 20 including, e.g., a resistor heating element, is built in below the grounding electrode 18. In accordance with the present invention, the grounding electrode 18 is grounded to a ground via a capacitor 22. In this embodiment, the capacitor 22 is a fixed one whose capacitance is constant.

The heater 20 is supplied with electricity from a heater power supply 24 to generate heat. The heat generated in the heater 20 is dissipated through the mesh-like grounding electrode 18 and then configured to be transferred to the semiconductor wafer W on the wafer mounting surface 12a.

Provided on the chamber ceiling above the stage 12 is an upper electrode 26 facing the grounding electrode 18. The upper electrode 26 has a function of a shower head for supplying a process gas toward the semiconductor wafer W on the stage 12 and is provided with a plurality of gas injection openings 26a and a gas manifold (buffer chamber) 26b. The shower head 26 has a gas inlet port 26c to which a gas supply line 30 leading from a gas supply unit 28 is connected by way of an insulating connecting member 27. A opening/closing valve 32 is provided on the gas supply line 30.

The gas supply unit 28 includes a process gas supply system for supplying a gas for Ti film formation and a cleaning gas supply system for supplying a cleaning gas for dry cleaning operation. The process gas supply system includes a part for supplying a Ti-containing gas (usually, Ti compound gas, e.g., a TiCl gas), a part for supplying a reducing gas (e.g., H₂ gas) and a part for supplying a rare gas (e.g., an Ar gas). The cleaning gas supply system includes a ClF₃ gas supply part for supplying, e.g., a ClF₃ gas as the cleaning gas and a N₂ gas supply part for supplying, e.g., a N₂ gas as a dilution gas. Each of the gas supply parts is provided with an opening/closing valve and a mass flow controller (MFC).

A predetermined frequency, e.g., a high frequency of 450 kHz, is applied with a prescribed intensity to the upper electrode 26 from a high-frequency power supply 34 via a matching unit 36 during the film formation process. If the high frequency is applied to the upper electrode 26 from the high-frequency power supply 34, a glow discharge will occur between the grounding electrode 18 and the upper electrode 26 to generate a reaction gas plasma in a space above the stage 12. In this embodiment, the high frequency for generating the plasma may be an arbitrary one but should preferably be in the range of 450 kHz to 2 MHz wherein the deposition (electrically conductive film) formed on the substrate and the electrodes as well as around the substrate is substantially negligible. The upper electrode 26 is electrically insulated from the chamber 10 by means of a ring-like insulator 38.

An evacuation port 40 is provided on the bottom of the chamber 10 and an gas evacuation unit 44 is connected to the evacuation port 40 through an evacuation pipe 42. The gas evacuation unit 44 has a vacuum pump and is capable of depressurizing the processing space within the chamber 10 to a desired vacuum pressure. A gate valve 46 for opening and closing an entrance for the semiconductor wafer W is attached to a side wall of the chamber 10.

At the time when a Ti film formation process is executed with respect to the semiconductor wafer W on the stage 12 in the plasma CVD equipment, the above-noted process gases (a TiCl₄ gas, a H₂ gas, an Ar gas and the like) are introduced into the chamber 10 from the gas supply unit 28 with a predetermined mixing ratio and a flow rate, and the pressure within the chamber 10 is regulated to a set value by the gas evacuation unit 44. In addition, the high frequency is supplied to the upper electrode 26 from the high-frequency power supply 34 with a predetermined intensity. The heater 20 in the stage 12 is energized by the heater power supply 24, thereby generating heat, which, in turn, heats the wafer mounting surface 12a up to a predetermined temperature (e.g., 350-700° C.). The process gases discharged from the gas injection openings 26a of the upper electrode (shower head) 26 are transformed into a plasma in the midst of glow discharge occurring between the upper electrode 26 and the bottom electrode (grounding electrode) 12. The plasma produces radicals and/or ions which, in turn, are impinged on a major surface (top surface) of the semiconductor wafer W to induce a surface reaction (reducing reaction of TiCl₄ and H₂), thus forming a Ti film.

A typical application of the Ti film formation through the use of the plasma CVD equipment can be found in a barrier metal formed in advance of filling up a wiring line connection holes (contact holes, via holes and the like). Such kind of barrier metals has to be coated on the inner wall of the wiring line connection holes at a high aspect ratio. To this end, process parameters such as a gas flow rate, a pressure, a temperature and the like are controlled to be in optimized values.

Concomitantly with the formation of the Ti film on the semiconductor wafer W, however, unwanted depositions are formed on the respective parts within the chamber 10, particularly on the stage 12 heated together with the wafer. Such depositions are accumulated and built up in proportion to an increase in the number of wafers processed and the number of times of the film formation process executed. The depositions tend to become a cause of particle generation when peeled off. Taking this into account, the plasma CVD equipment is designed such that the chamber is dry-cleaned at every ₅₀₀^{th} cycle of the film formation process (for every 500 substrates processed) to restore the respective parts in the chamber to an initial state free from the depositions.

During the course of the dry-cleaning process, the above-noted cleaning gases (a ClF₃ gas, a N₂ gas and the like) are introduced into the chamber 10 from the gas supply unit 28 with a predetermined mixing ratio and flow rate under a state where no semiconductor wafer W is placed on the stage 12, and the pressure within the chamber 10 is regulated to a set value by the gas evacuation unit 44. Since the ClF₃ gas-based dry cleaning operation requires no plasma, the high-frequency power supply 34 may be turned off. Although it is desirable to energize the heater 20 and heat the stage 12 up to an appropriate temperature, the dry cleaning operation may be also performed at a room temperature.

The ClF₃ gas discharged from the gas injection openings 26a of the shower head 26 is widely spread covering every corner within the chamber 10 and reacts with the depositions or deposited layers on the respective parts to etch the same. The reaction products evaporated from the respective parts by the etching action are evacuated, as an exhaust gas out of the chamber 10 through the evacuation port 40.

Periodic execution of such a dry cleaning operation helps avoid situations where the undesirable depositions formed in the chamber 10 are built up beyond a permissible extent.

During one dry cleaning cycle, i.e., 500 times of film formation process, the impedance against the high frequency supplied from the high-frequency power supply 34 is gradually reduced as the depositions are built up in the chamber 10. This leads to a gradual increase in the voltage applied to the semiconductor wafer W (in the potential difference of the wafer). Among the impedance reductions occurring in the chamber, the reduction in the impedance of the stage 12, namely the impedance (stage impedance) between the semiconductor wafer W and the grounding electrode 18, is apparent and predominant.

In the plasma CVD equipment of the present embodiment, a capacitor 22 is provided between the grounding electrode 18 and the ground in an effort to compensate the in-chamber impedance reduction, particularly the stage impedance reduction. The capacitor 22 is serially connected to the stage impedance to ensure that the total impedance becomes greater than the stage impedance in itself, thus making compensation for the reduction in the stage impedance.

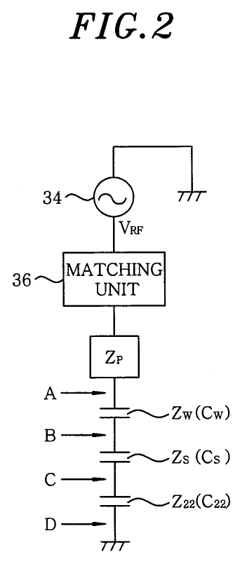

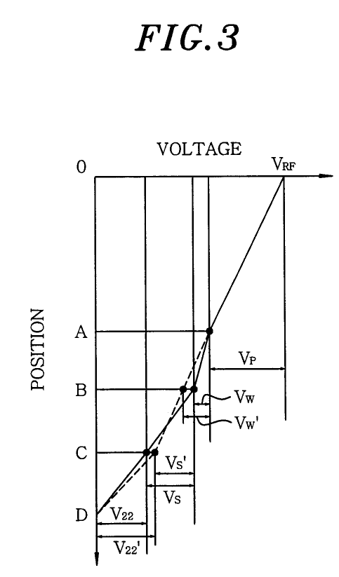

Operation of the capacitor 22 employed in the present embodiment will be described below in more detail with reference to FIGS. 2 and 3.

FIG. 2 illustrates an equivalent circuit of the high frequency impedance within the chamber 10 of the plasma CVD equipment. In the equivalent circuit, Z_{P} denotes an impedance of a plasma generated in a space above the stage 12 (a space between the upper electrode 26 and the semiconductor wafer W). Z_{W} represents the impedance of the semiconductor wafer W lying between the plasma and the stage 12 and can be approximated by using a capacitive load (capacitor) C_{W}. Z_{S} stands for a stage impedance between the semiconductor water W and the grounding electrode 18 and can be approximated by using a capacitive load (capacitor) C_{S}. Z₂₂ is an impedance of the capacitor 22 and can be approximated by using a capacitive load (capacitor) C₂₂. A matching unit 36 serves to match the output or transfer impedance of the high-frequency power supply 34 with the impedance of the load.

FIG. 3 schematically represents a potential distribution in the equivalent circuit noted above. If the voltage drop in the matching unit 36 is neglected, the high frequency voltage V_{RF} (peak-to-peak value) will be divided into V_{P}, V_{W}, V_{S} and V₂₂, respectively, in the plasma impedance Z_{P}, the wafer impedance Z_{W}, the stage impedance Z_{S} and the capacitor 22, all of which are connected in series. In other words, V_{P} is the voltage applied to the plasma; V_{W} is the voltage applied to the semiconductor wafer W; V_{S} is the voltage applied to the wafer mounting surface 12a of the stage 12; and V₂₂ is the voltage applied to the capacitor 22.

As set forth above, the depositions in the chamber 10 is accumulated or built up as the film formation process is repeatedly performed during the dry cleaning cycle. At this time, the stage impedance Z_{S} among the impedances in the chamber 10 undergoes a significant reduction. In other words, if Ti-based deposit films adhered to around the stage 12 are increased, the capacity (capacitance C_{S}) of the stage impedance Z_{S} will be also increased, thus reducing the stage impedance Z_{S}.

Compared to the variation (reduction) in the stage impedance Z_{S}, the variation in the plasma impedance Z_{P} or the water impedance Z_{W} is small enough to be neglected. The impedance matching rendered by the matching unit 36 also acts to maintain the voltage V_{P} constant in general, the V_{P} being mainly applied to the plasma impedance Z_{P}.

In the plasma CVD equipment, the capacitor 22 is inserted between the grounding electrode 18 and the ground such that the grounding electrode 18, the capacitor 22 and the ground are connected in series, thus reducing the voltage division ratio that the stage impedance Z_{S} shares in the total serial impedance. This helps reduce the diminishing ratio of the divided voltage V_{S} otherwise stemming from the reduction in the stage impedance Z_{S}. Furthermore, the increment of voltage diverted to other impedances as a result of the reduction in the divided voltage V_{S} of the stage impedance Z_{S} is dividedly shared by the wafer impedance Z_{W} and the capacitor 22. This significantly suppresses the increase or rise in the voltage (water potential difference) V_{W} applied to the semiconductor wafer W, precluding the possibility that the semiconductor wafer W is damaged by an abnormal electric discharge or other causes.

Referring to FIG. 3, the solid line indicates a potential distribution in an initial state of the dry cleaning cycle, and the dotted line shows a potential distribution at the end of the dry cleaning cycle. If the voltage applied to the stage impedance Z_{S} during the dry cleaning cycle is reduced from V_{S} to V_{S}′, the voltages applied to the semiconductor wafer W and the capacitor 22 will be, respectively, increased from V_{W} and V₂₂ to V_{W}′ and V₂₂′. It can be seen that, among others, the increase (V_{W}→V_{W}′) in the voltage applied to the semiconductor wafer W is not so great.

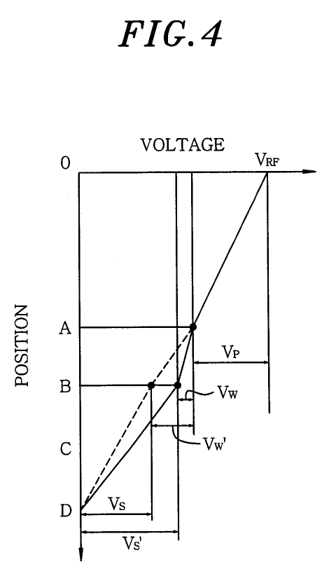

FIG. 4 schematically represents a potential distribution in the high frequency impedance within the chamber 10 in a comparative example wherein the capacitor 22 is excluded from use. In this figure, the solid line indicates a potential distribution in an initial state of the dry cleaning cycle, and the dotted line shows a potential distribution at the end of the dry cleaning cycle.

In case the capacitor 22 is not inserted between the grounding electrode 18 and the ground, the voltage division ratio that the stage impedance Z_{S} shares in the total serial impedance becomes great. This increases the diminishing ratio of the divided voltage V_{S} accompanying the reduction in the stage impedance Z_{S}. Most of the increment in voltage being diverted to other impedances as a result of the reduction in the divided voltage V_{S} is concentrated on the water impedance Z_{W}, leading to a sharp increase in voltage V_{W}, applied to the semiconductor wafer W.

In the present embodiment, a fixed capacitor is used as the capacitor 22 and therefore it is important to properly select the capacitance (fixed value) thereof In the following, description will be given to one exemplary method for selecting the capacitance of the capacitor 22.

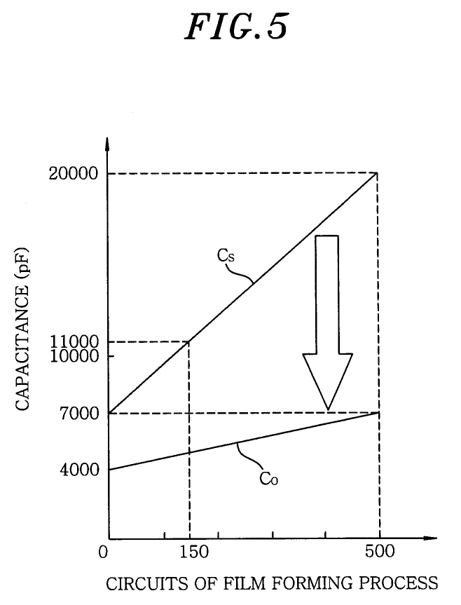

As mentioned above, the stage impedance Z_{S} is substantially a capacitive load (capacitor), and the capacitance C_{S} thereof is increased in proportion to the number of times of the film formation process conducted during the dry cleaning cycle. For example, as illustrated in FIG. 5, the capacitance C_{S} may be as low as 7,000 pF at the beginning of the dry cleaning cycle but could soar up to 20,000 pF at the end of the dry cleaning cycle. In the present invention, the capacitor 22 is serially connected to the stage impedance Z_{S}. Accordingly, if the capacitance of the capacitor 22 is assumed to be C₂₂, the total capacitance C₀ is represented by the following equation Eq. 1:

C₀=C_{S}×C₂₂/(C_{S}+C₂₂) (Eq. 1)

The smaller the capacitance C₂₂ of the capacitor 22 becomes, so does the total capacitance C₀, meaning that the increment in the capacitance C_{S} can be cancelled strongly. If, however, the total capacitance C₀ is too small, the impedance will grow too higher, thereby adversely affecting the plasma generation efficiency, the plasma distribution and the process thereof. In other words, there exists a zone where the plasma becomes unstable depending on the capacity of the chamber impedance, and the zone has to be avoided.

According to one aspect of the present invention, the capacitance C₂₂ of the capacitor 22 is selected such that the total capacitance C₀ at the end of the dry cleaning cycle (when the 500th substrate is processed) can be substantially equal to or similar to the stage capacitance C_{S} at the beginning of the dry cleaning cycle (when the first substrate is processed). Accordingly, if C_{S} is equal to 20,000 F and C₀ is equal to 7,000 pF in the example illustrated in FIG. 5, the capacitance C₂₂ of the capacitor 22 will be about 10,000 pF, when found using the following equation Eq. 2 which is a modification of the above-noted equation Eq. 1:

$${C}_{22} = {C}_{s} \times {C}_{0} / ( {C}_{s} - {C}_{0} ) \\ = 7000 \times 20000 / ( 20000 - 7000 ) \\ = 10769 \qquad ( Eq . 2 )$$

By selecting the capacitance C₂₂ of the capacitor 22 in the method set forth above, it is possible to compensate the increase in the stage capacitance C_{S} (the decrease in the stage impedance Z_{S}) from the beginning to the end of the dry cleaning cycle without affecting the plasma or the process, thereby suppressing any increase in the voltage V_{W} applied to the semiconductor water W.

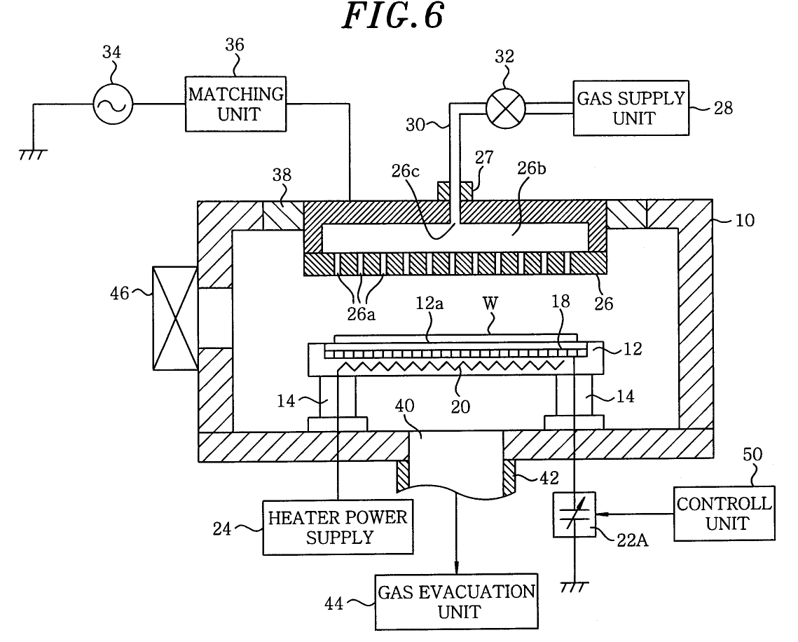

Although a capacitor with a constant capacitance was used as the capacitor 22 in the embodiment described above, it is equally possible, as in the embodiment illustrated in FIG. 6, to use a variable capacitor whose capacitance is variable, as the capacitor 22A corresponding to the above-noted capacitor 22. Parts other than the capacitor 22A in FIG. 6 are the same as those described above and, therefore, will be designated by like reference numerals, while the description thereof will be omitted in that regard.

In the above embodiment, a control unit 50 variably controls the capacitance C₂₂ of the variable capacitor 22A in association with the dry cleaning cycle. For example, the variable control characteristic of the capacitance C₂₂ for maintaining constantly the total capacitance C₀ throughout the dry cleaning cycle can be realized by, as in the foregoing equation Eq. 2, fixing the total capacitance C₀ to a constant value (integer) and allowing the capacitance C₂₂ of the variable capacitor 22A to become a function of the stage capacitance C_{S} (still more, the number of times of the film formation process).

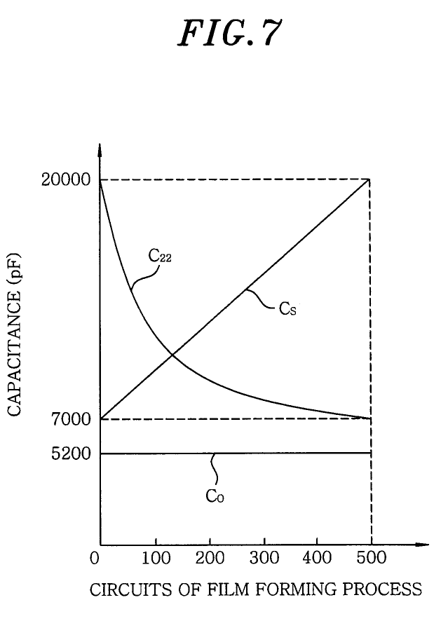

One example of the variable control characteristic is shown in FIG. 7. By making a proper variable control for the capacitance C₂₂ of the variable capacitor 22A based on the number of times of the film formation process, it becomes possible either to maintain the total capacitance C₀ equal to an initial value (7,000 pF) of the stage capacitance C_{S} or to change the total capacitance C₀ as an arbitrary function throughout the dry cleaning cycle.

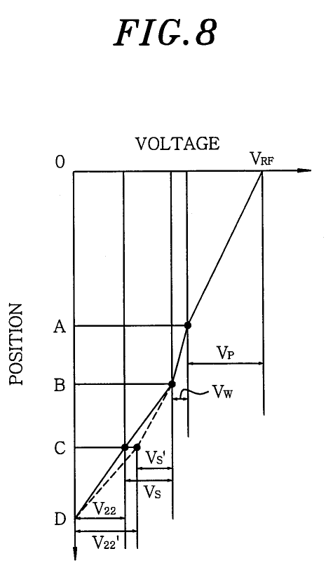

According to the method of variably controlling the capacitance C₂₂ of the variable capacitor 22A in the above manner, even if the voltage applied to the stage impedance Z_{S} during the dry cleaning cycle is decreased from V_{S} to V_{S}′ as illustrated in FIG. 8, all of the increment in voltage diverted to other impedances can be applied substantially only to the capacitor 22A, thereby keeping substantially constant the voltage V_{S} applied to the semiconductor wafer W.

While the invention has been described with reference to one preferred embodiment, it will be apparent to those skilled in the art that a variety of modifications or changes may be made without departing from the scope of the invention.

Taking some examples, respective parts within the chamber 12, particularly the stage 12 or the upper electrode 26 may be formed in a different configuration and manner, and the dry cleaning cycle may be set to an arbitrary time period (an arbitrary number of times of processes or number of substrates processed). In the configuration (shown in FIG. 1) that makes use of a fixed capacitor as the capacitor 22, a switch may be provided for selectively inserting the capacitor 22 between the grounding electrode 18 and the ground. In this case, it is possible to directly connect the grounding electrode 18 to the ground without inserting the capacitor 22 for a while, e.g., immediately after commencement of the dry cleaning cycle, and then to insert the capacitor 22 sometime during the dry cleaning cycle (e.g., from the time of processing the 150th substrate). Likewise, the switch type configuration may be equally employed in case of using a variable capacitor as the capacitor 22.

The present invention provides a great effect in the plasma CVD equipment for formation of a Ti film as set forth above. However, the present invention may be applied to a plasma CVD equipment for forming metal films other than the Ti film, and still more to a plasma CVD equipment for forming conductive films made of Si, metallic compounds, noble metal oxides or the like.

Although the stage impedance is the main variation part of the in-chamber impedances in the foregoing embodiment, other parts inside and outside the chamber may constitute the main variation part of impedance, depending on the kind of film forming materials, the chamber structure or the like, and the capacitive voltage dividing configuration may be applied thereto as in the foregoing embodiment. The substrate to be processed is not restricted to the semiconductor wafer but may include a variety of substrates for an FPD, photo masks, CD substrates, printed boards and so forth.

### INDUSTRIAL APPLICABILITY

By virtue of the configuration and operation described above, the plasma CVD equipment of the present invention can suppress any increase in the voltage applied to a substrate to be processed despite the repeated execution of film formation process during a dry-cleaning cycle, thereby avoiding any damage to the substrate and improving a production yield.

What is claimed is:

1. A plasma CVD method for use in a plasma CVD apparatus including a chamber, an insulator stage for mounting thereon a substrate to be processed, a grounding electrode embedded in the stage, a high frequency electrode provided within the chamber to face the grounding electrode, and a high frequency power supply for supplying a high frequency power to the high frequency electrode, the method comprising:
installing a fixed capacitor between the grounding electrode and a ground; and
supplying the high frequency power to the high frequency electrode to perform a plasma CVD within the chamber,
wherein the capacitor suppresses an increase in a voltage applied to the substrate, the increase in the voltage being caused by reduction in a stage impedance between the grounding electrode and the substrate as the plasma CVD is repeatedly carried out.

2. The plasma CVD method of claim 1, wherein a capacitance of the capacitor is selected such that a total impedance of an impedance of the capacitor and the stage impedance at a time when one period of the plasma CVD is completed is substantially identical or approximate to the stage impedance at a time when said one period is started, and wherein the plasma CVD is repeated a predetermined number of times within said one period.

3. A plasma CVD method for use in a plasma CVD apparatus including a chamber, an insulator stage for mounting thereon a substrate to be processed, a grounding electrode embedded in the stage, a high frequency electrode provided within the chamber to face the grounding electrode, and a high frequency power supply for supplying a high frequency power to the high frequency electrode, the method comprising:
installing a fixed capacitor between the grounding electrode and a ground; and
supplying the high frequency power to the high frequency electrode to perform a plasma CVD within the chamber,
wherein the capacitor suppresses an increase in a voltage applied to the substrate, the increase in the voltage being caused by reduction in a chamber impedance between the high frequency electrode and the grounding electrode as the plasma CVD is repeatedly carried out.

4. The plasma CVD method of claim 3, wherein a capacitance of the capacitor is selected such that a total impedance of an impedance of the capacitor and the chamber impedance at a time when one period of the plasma CVD is completed is substantially identical or approximate to the chamber impedance at a time when said one period is started, and wherein the plasma CVD is repeated a predetermined number of times within said one period.

5. A plasma CVD method for use in a plasma CVD apparatus including a chamber, an insulator stage for mounting thereon a substrate to be processed, a grounding electrode embedded in the stage, a high frequency electrode provided within the chamber to face the grounding electrode, and a high frequency power supply for supplying a high frequency power to the high frequency electrode, the method comprising:
installing a variable capacitor between the grounding electrode and a ground;
supplying the high frequency power to the high frequency electrode to perform a plasma CVD within the chamber; and
variably controlling the variable capacitor to suppress an increase in a voltage applied to the substrate, the increase in the voltage being caused by reduction in a stage impedance between the grounding electrode and the substrate as the plasma CVD is repeatedly carried out.

6. The plasma CVD method of claim 5, wherein a capacitance of the variable capacitor is variably controlled in such a manner that a total impedance of an impedance of the variable capacitor and the stage impedance is maintained to be substantially constant throughout one period of the plasma CVD, wherein the plasma CVD is repeated a predetermined number of times within said one period.

7. A plasma CVD method for use in a plasma CVD apparatus including a chamber, an insulator stage for mounting thereon a substrate to be processed, a grounding electrode embedded in the stage, a high frequency electrode provided within the chamber to face the grounding electrode, and a high frequency power supply for supplying a high frequency power to the high frequency electrode, the method comprising:
installing a variable capacitor between the grounding electrode and a ground;
supplying the high frequency power to the high frequency electrode to perform a plasma CVD within the chamber; and
variably controlling the variable capacitor to suppress an increase in a voltage applied to the substrate, the increase in the voltage being caused by reduction in a chamber impedance between the high frequency electrode and the grounding electrode as the plasma CVD is repeatedly carried out.

8. The plasma CVD apparatus of claim 7, wherein a capacitance of the variable capacitor is variably controlled in such a manner that a total impedance of an impedance of the variable capacitor and the chamber impedance is maintained to be substantially constant throughout one period of the plasma CVD, wherein the plasma CVD is repeated a predetermined number of times within said one period.

9. The plasma CVD method of claim 1, wherein the stage is made of AlN.

10. The plasma CVD method of claim 3, wherein the stage is made of AlN.

11. The plasma CVD method of claim 1, wherein the grounding electrode is formed of a mesh shape.

12. The plasma CVD method of claim 3, wherein the grounding electrode is formed of a mesh shape.

13. The plasma CVD method of claim 1, further comprising decomposing a source gas including TiCl₄, and Ti film is formed on the substrate.

14. The plasma CVD method of claim 3, further comprising decomposing a source gas including TiCl₄, and Ti film is formed on the substrate.

15. The plasma CVD method of claim 1, wherein a frequency of the high frequency is selected within a range from 450 kHz to 2 MHz.

16. The plasma CVD method of claim 3, wherein a frequency of the high frequency is selected within a range from 450 kHz to 2 MHz.
